(19) United States
(12) Patent Application Publication
(10) Pub. No.: US 2025/0120294 A1
(43) Pub. Date: Apr. 10, 2025

(54) DISPLAY DEVICE AND METHOD OF MANUFACTURING THE SAME

(71) Applicant: Samsung Display Co., LTD., Yongin-si (KR)

(72) Inventors: KEUNWOO PARK, Yongin-si (KR); MIN-JAE KIM, Yongin-si (KR); KYUNGHAE PARK, Yongin-si (KR); INSEOK SONG, Yongin-si (KR)

(21) Appl. No.: 18/903,966

(22) Filed: Oct. 1, 2024

(30) Foreign Application Priority Data
Oct. 10, 2023 (KR) 10-2023-0134687

(51) Int. Cl. H10K 59/80; H10K 59/12; H10K 59/122; H10K 59/38

(52) U.S. Cl. CPC H10K 59/8792; H10K 59/1201; H10K 59/122; H10K 59/38; H10K 59/878

(57) ABSTRACT

A display device includes a substrate defining a light-emitting area and a light-blocking area adjacent to the light-emitting area, a light-blocking pattern at the light-blocking area on the substrate, a transmission bank on the light-blocking pattern and defining a first opening exposing at least a portion of the light-blocking pattern, and a reflection pattern on the light-blocking pattern exposed by the first opening of the transmission bank and the transmission bank.

### CROSS-REFERENCE TO RELATED APPLICATION(S)

The present application claims priority to and the benefit of Korean Patent Application No. 10-2023-0134687, filed on Oct. 10, 2023, in the Korean Intellectual Property Office, the entire disclosure of which is incorporated herein by reference.

### BACKGROUND

### 1. Field

One or more embodiments of the present disclosure may be related to a display device that provides visual information, and a method of manufacturing the same.

### 2. Description of the Related Art

A display device may include a light-emitting layer and a color conversion layer to improve display quality. Light may be emitted from the light-emitting layer, and the color conversion layer may convert a wavelength of the light emitted from the light-emitting layer. Accordingly, the color conversion layer may emit light in a wavelength band different from that of the incident light.

The color conversion layer may include wavelength conversion particles such as quantum dots. For example, the color conversion layer may be divided into a red color conversion pattern, a green color conversion pattern, and a transmission pattern (or a blue color conversion pattern).

### SUMMARY

Embodiments provide a display device with improved display quality.

Embodiments provide a method of manufacturing the display device.

According to one or more embodiments of the present disclosure, a display device may include: a substrate defining a light-emitting area and a light-blocking area adjacent to the light-emitting area; a light-blocking pattern at the light-blocking area on the substrate; a transmission bank on the light-blocking pattern and defining a first opening exposing at least a portion of the light-blocking pattern; and a reflection pattern on the light-blocking pattern exposed by the first opening and the transmission bank.

The reflection pattern may extend from an upper surface of the light-blocking pattern to an upper surface of the transmission bank along a side surface of the first opening.

A thickness of the light-blocking pattern may be less than or equal to about 1 μm.

A width of the light-blocking pattern may be greater than or equal to a width of the first opening.

The width of the light-blocking pattern may be less than or equal to a width of the transmission bank.

The display device may further include: a color conversion pattern at the light-emitting area on the substrate.

The transmission bank may further define a second opening overlapping the light-emitting area, and the color conversion pattern is in the second opening.

The display device may further include: a transmission pattern at the light-emitting area on the substrate.

The transmission pattern may be in the second opening and on the reflection pattern.

The reflection pattern may include metal.

The display device may further include: a light-emitting layer between the substrate and the light-blocking pattern.

According to one or more embodiments of the present disclosure, a method for manufacturing a display device may include: forming a light-blocking pattern at a light-blocking area on a substrate defining the light-blocking area and a light-emitting area adjacent to the light-blocking area; forming a transmission bank on the light-blocking pattern defining a first opening exposing at least a portion of the light-blocking pattern; and forming a reflection pattern on the light-blocking pattern exposed by the first opening and the transmission bank.

The reflection pattern may extend from an upper surface of the light-blocking pattern to an upper surface of the transmission bank along a side surface of the first opening.

A thickness of the light-blocking pattern may be less than or equal to about 1 μm.

A width of the light-blocking pattern may be greater than or equal to a width of the first opening.

The width of the light-blocking pattern may be less than or equal to a width of the transmission bank.

The method may further include forming a color conversion pattern at the light-emitting area on the substrate after forming the transmission bank and before forming the reflection pattern.

The transmission bank may further define a second opening overlapping the light-emitting area, and the color conversion pattern is formed in the second opening.

The method may further include forming a transmission pattern at the light-emitting area on the substrate after forming the reflection pattern.

The transmission pattern may be formed in the second opening and on the reflection pattern.

The method may further include forming a light-emitting layer on the substrate before forming the light-blocking pattern.

In a display device according to one or more embodiments of the present disclosure, the display device may include a light-blocking pattern, a transmission bank, and a reflection pattern. The light-blocking pattern may include a material having a relatively high absorbance. The light-blocking pattern may absorb light toward adjacent pixels among incident light emitted by a light-emitting element, and color mixing between pixels adjacent to each other may be prevented or reduced.

In a process of forming the transmission bank, because an unnecessary portion of the transmission bank due to exposure reflection may not be formed by the light-blocking pattern, light transmitted through the transmission bank and not reflected by the reflection pattern may be minimized or reduced. Accordingly, color mixing between pixels adjacent to each other may be further prevented or reduced. In some embodiments, because light transmitted through the transmission bank is reflected by the reflection pattern, light efficiency of the display device may be improved.

### BRIEF DESCRIPTION OF THE DRAWINGS

FIG. 1 is a perspective view illustrating a display device according to one or more embodiments of the present disclosure.

FIG. 2 is a cross-sectional view taken along the line I-I′ of FIG. 1, according to one or more embodiments of the present disclosure.

FIG. 3 is a cross-sectional view taken along the line II-II′ of FIG. 1, according to one or more embodiments of the present disclosure.

FIGS. 4 and 5 are enlarged cross-sectional views of area A of FIG. 3, according to one or more embodiments of the present disclosure.

FIGS. 6, 7, 8, 9, 10, 11, 12, 13, and 14 are cross-sectional views illustrating a method of manufacturing the display device of FIG. 3, according to one or more embodiments of the present disclosure.

FIG. 15 is a cross-sectional view illustrating a display device, according to one or more embodiments of the present disclosure.

FIG. 16 is a cross-sectional view illustrating a display device, according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

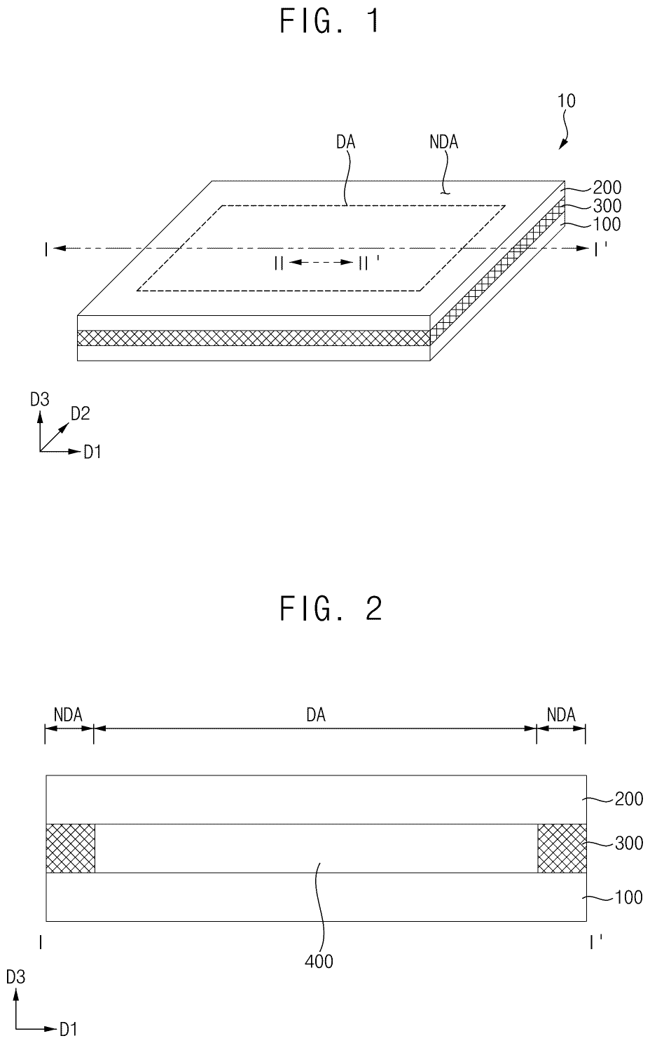

FIG. 1 is a perspective view illustrating a display device according to some embodiments of the present disclosure.

Referring to FIG. 1, a display device 10 may include a display area DA and a non-display area NDA.

A plurality of pixels may be arranged in the display area DA. The plurality of pixels may be arranged in a matrix form along a first direction D1, and along a second direction D2 intersecting the first direction D1. For example, the first direction D1 may be normal (e.g., perpendicular) to the second direction D2. Each of the plurality of pixels may emit light. As each of the plurality of pixels emits light, the display area DA may display an image.

Lines connected to the plurality of pixels may be further arranged in the display area DA. For example, the lines may include a data signal line, a gate signal line, a power line, and/or the like.

The non-display area NDA may be an area that does not display an image. The non-display area NDA may be located around the display area DA. For example, the non-display area NDA may surround the display area DA (e.g., in plan view).

Drivers that drive the plurality of pixels may be arranged in the non-display area NDA. For example, the drivers may include a data driver, a gate driver, a power voltage generator, a timing controller, and/or the like. The plurality of pixels may emit light based on signals received from the drivers.

FIG. 2 is a cross-sectional view taken along the line I-I′ of FIG. 1.

Referring to FIGS. 1 and 2, the display device 10 may include a first structure 100, a second structure 200, and a sealing member 300.

The second structure 200 may be arranged on the first structure 100. The first structure 100 and the second structure 200 may face each other. The second structure 200 may be spaced apart from the first structure 100 in a third direction D3 crossing each of the first direction D1 and the second direction D2. For example, the third direction D3 may be normal (e.g., perpendicular) to each of the first direction D1 and the second direction D2.

Accordingly, a space 400 may be defined between the first structure 100 and the second structure 200. The space 400 may include a gap between the first structure 100 and the second structure 200. In one or more embodiments, the space 400 may be filled with a filler. For example, the filler may include an organic material such as silicone resin, epoxy resin, and/or the like, air, and/or the like. In one or more embodiments, the filler may further include a material for matching a refractive index. In one or more other embodiments, the space 400 may be in a vacuum state.

The first structure 100 may be a substrate including a light-emitting element. The light-emitting element may be arranged in the display area DA, and may generate light according to a driving signal. The second structure 200 may be a substrate including a color filter layer that selectively transmits light in certain wavelength band or bands.

The sealing member 300 may be arranged between the first structure 100 and the second structure 200. The sealing member 300 may be arranged along the non-display area NDA. The sealing member 300 may be arranged in the non-display area NDA along edges of the first structure 100 and the second structure 200. For example, the sealing member 300 may be arranged between the first structure 100 and the second structure 200 to surround the display area DA in a plan view. The first structure 100 and the second structure 200 may be coupled by the sealing member 300.

Because the space 400 between the first structure 100 and the second structure 200 is sealed by the sealing member 300, external moisture, air, impurities, and/or the like may be prevented or reduced from penetrating into the space 400. In one or more embodiments, the sealing member 300 may maintain the space 400 between the first structure 100 and the second structure 200. For example, the sealing member 300 may include an organic material such as epoxy resin, and/or the like.

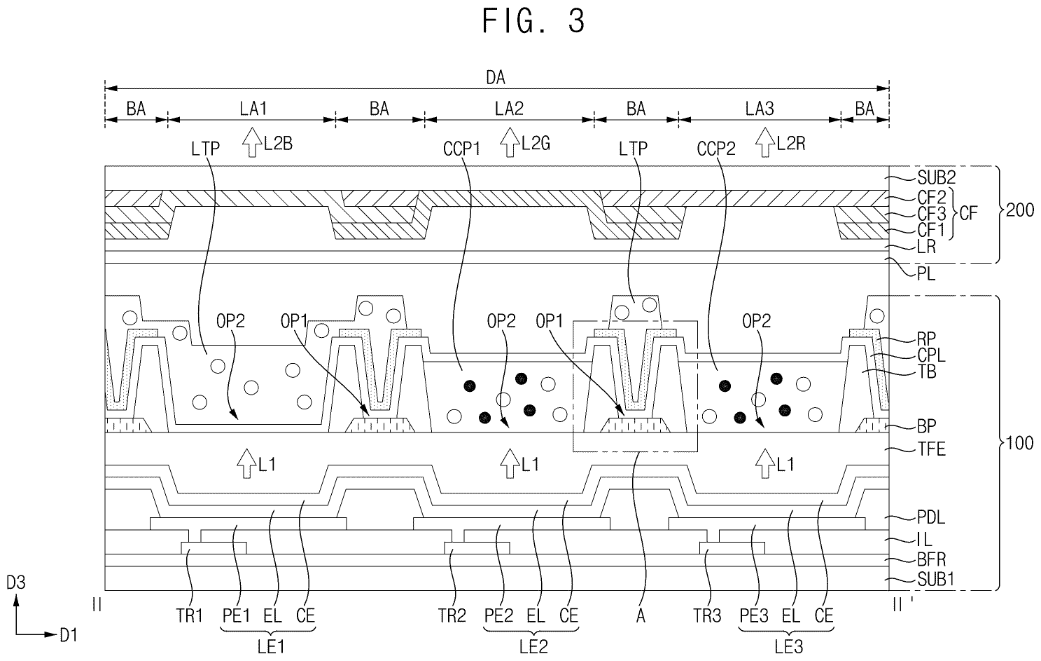

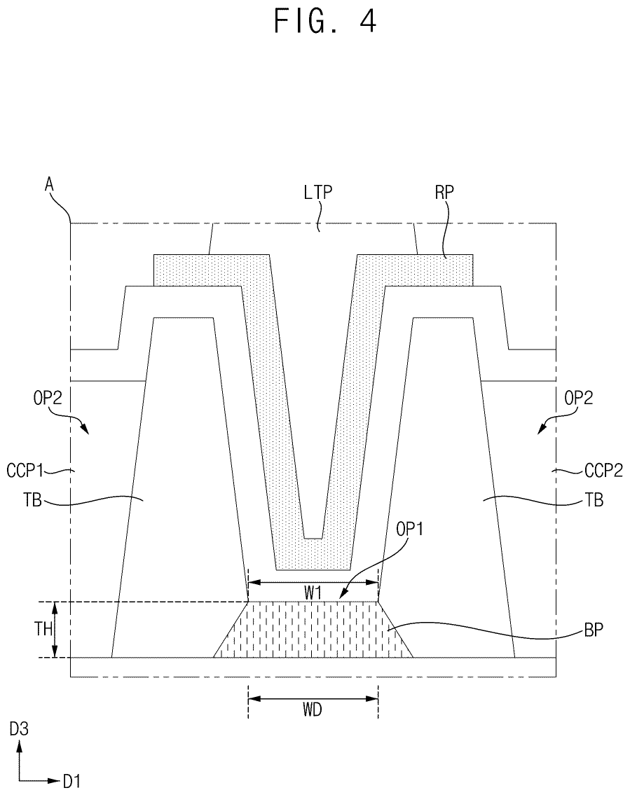

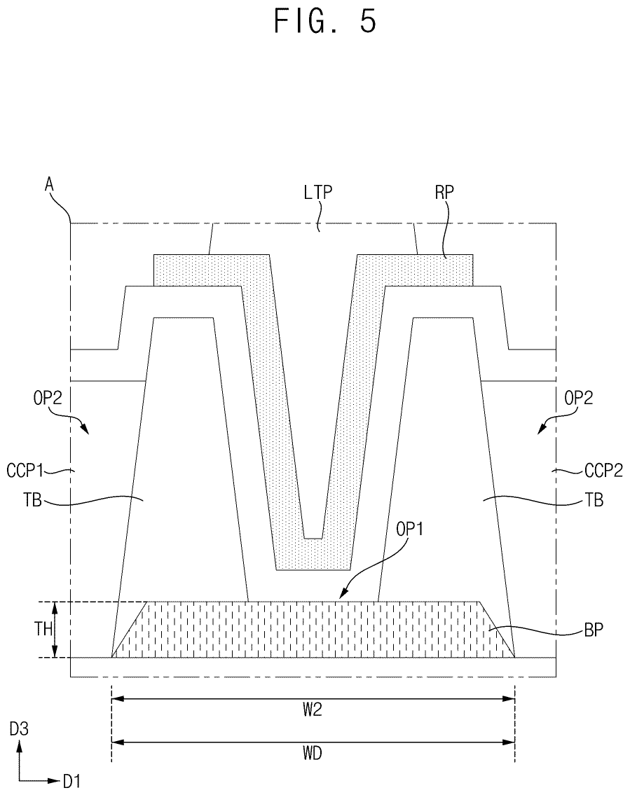

FIG. 3 is a cross-sectional view taken along the line II-II′ of FIG. 1. FIGS. 4 and 5 are enlarged cross-sectional views of area A of FIG. 3. For example, FIG. 3 may be a cross-sectional view illustrating an example of the display area DA included in the display device 10, and FIGS. 4 and 5 may be cross-sectional views illustrating a range of a width WD of a light-blocking pattern BP included in the display device 10.

Referring to FIGS. 1, 2, 3, 4, and 5, the display area DA may include a plurality of light-emitting areas and a light-blocking area BA. Each of the light-emitting areas may be an area that emits light.

Light (hereinafter, “incident light”) L1 generated in the first structure 100 may be emitted to outside through the light-emitting areas. The light-emitting areas may include a first light-emitting area LA1, a second light-emitting area LA2, and a third light-emitting area LA3.

The first, second, and third light-emitting areas LA1, LA2, and LA3 may emit light in different wavelength bands. For example, the first light-emitting area LA1 may emit first transmitted light L2B in a blue wavelength band, the second light-emitting area LA2 may emit second transmitted light L2G in a green wavelength band, and the third light-emitting area LA3 may emit third transmitted light L2R in a red wavelength band, but the present disclosure is not limited thereto.

In some embodiments, the first, second, and third light-emitting areas LA1, LA2, and LA3 may be spaced from each other in a plan view, and may be arranged to repeat. The light-blocking area BA may be located between the first, second, and third light-emitting areas LA1, LA2, and LA3 adjacent to each other. The light-blocking area BA may surround the first, second, and third light-emitting areas LA1, LA2, and LA3 in a plan view. For example, the light-blocking area BA may have a grid shape in the plan view. The light-blocking area BA may be an area that does not emit light.

In some embodiments, the first structure 100 may include a first substrate SUB1, a buffer layer BFR, first, second, and third transistors TR1, TR2, and TR3, an insulating layer IL, a pixel-defining layer PDL, first, second, and third light-emitting elements LE1, LE2, and LE3, an encapsulation layer TFE, a light-blocking pattern BP, a transmission bank TB, a first color conversion pattern CCP1, a second color conversion pattern CCP2, a capping layer CPL, a reflection pattern RP, and a transmission pattern LTP.

Here, the first light-emitting element LE1 may include a first pixel electrode PE1, a light-emitting layer EL, and a common electrode CE. The second light-emitting element LE2 may include a second pixel electrode PE2, the light-emitting layer EL, and the common electrode CE. The third light-emitting element LE3 may include a third pixel electrode PE3, the light-emitting layer EL, and the common electrode CE.

The first substrate SUB1 may include a transparent material or an opaque material. For example, the first substrate SUB1 may be made of a rigid glass substrate, a plastic substrate, a flexible film, a metal substrate, and/or the like. These may be utilized alone or in combination with each other. Because the display area DA of the display device 10 includes the first, second, and third light-emitting areas LA1, LA2, and LA3 and the light-blocking area BA, the first substrate SUB1 may also define the first, second, and third light-emitting areas LA1, LA2, and LA3 and the light-blocking area BA.

The buffer layer BFR may be arranged on the first substrate SUB1 (as used herein, “on” may mean “above”). The buffer layer BFR may prevent or reduce metal atoms or impurities from diffusing from the first substrate SUB1 to the first, second, and third transistors TR1, TR2, and TR3. In one or more embodiments, the buffer layer BFR may improve a flatness of a surface of the first substrate SUB1 if (e.g., when) the surface of the first substrate SUB1 is not substantially uniform. The buffer layer BFR may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), and/or the like. These materials may be utilized alone or in combination with each other.

The first, second, and third transistors TR1, TR2, and TR3 may be arranged on the buffer layer BFR. A channel layer of each of the first, second, and third transistors TR1, TR2, and TR3 may include a silicon semiconductor material or an oxide semiconductor material. Examples of the silicon semiconductor material may include amorphous silicon, polycrystalline silicon, and/or the like. Examples of the oxide semiconductor material may include indium gallium zinc oxide (IGZO), indium tin zinc oxide (ITZO), and/or the like. These may be utilized alone or in combination with each other.

The insulating layer IL may be arranged on the buffer layer BFR, and may cover the first, second, and third transistors TR1, TR2, and TR3. The insulating layer IL may include an inorganic material such as silicon oxide, silicon nitride, silicon carbide, silicon oxynitride, silicon oxycarbide, and/or the like. In one or more embodiments, the insulating layer IL may include an organic material such as phenol resin, acrylic resin, polyimide resin, polyamide resin, siloxane resin, epoxy resin, and/or the like. These may be utilized alone or in combination with each other.

The first, second, and third pixel electrodes PE1, PE2, and PE3 may be arranged on the insulating layer IL. The first, second, and third pixel electrodes PE1, PE2, and PE3 may overlap the first, second, and third light-emitting areas LA1, LA2, and LA3, respectively. The first, second, and third pixel electrodes PE1, PE2, and PE3 may be connected to the first, second, and third transistors TR1, TR2, and TR3 through contact holes formed in the insulating layer IL, respectively. Each of the first, second, and third pixel electrodes PE1, PE2, and PE3 may include a metal, an alloy, a metal nitride, a conductive metal oxide, a transparent conductive material, and/or the like. They may be utilized alone or in combination with each other.

The pixel-defining layer PDL may be arranged on the insulating layer IL, and may cover at least a portion of each of the first, second, and third pixel electrodes PE1, PE2, and PE3. In other words, the pixel-defining layer PDL may define an opening exposing at least a portion of an upper surface of each of the first, second, and third pixel electrodes PE1, PE2, and PE3. The pixel-defining layer PDL may include an organic material, such as epoxy resin, siloxane resin, and/or the like.

The light-emitting layer EL may be arranged on the first, second, and third pixel electrodes PE1, PE2, and PE3 exposed by the pixel-defining layer PDL and the pixel-defining layer PDL. In some embodiments, the light-emitting layer EL may extend continuously in the display area DA across a plurality of pixels. For example, the light-emitting layer EL may entirely or substantially overlap the first, second, and third light-emitting areas LA1, LA2, and LA3 and the light-blocking area BA. In one or more other embodiments, the light-emitting layer EL may be separated from a light-emitting layer of an adjacent pixel. For example, the light-emitting layer EL may overlap the first, second, and third light-emitting areas LA1, LA2, and LA3, respectively, and may not overlap the light-blocking area BA.

The light-emitting layer EL may include at least one of an organic material or quantum dots that emit light of a certain color (e.g., a preset color). For example, the light-emitting layer EL may emit light in a blue wavelength band, but the present disclosure is not limited thereto. The light-emitting layer EL may have a multilayer structure. Functional layers, such as a hole injection layer, a hole transport layer, an electron transport layer, an electron injection layer, and/or the like, may be arranged on or below the light-emitting layer EL.

In some embodiments, the light-emitting layer EL may have a structure in which a plurality of organic light-emitting layers that emit light in a blue wavelength band are stacked. For example, the light-emitting layer EL may have a structure in which three blue organic light-emitting layers are stacked. However, the present disclosure is not limited thereto. In some embodiments, the light-emitting layer EL may have a structure in which a plurality of organic light-emitting layers that emit light in a blue wavelength band, and an organic light-emitting layer that emits light in a different wavelength band, are stacked. For example, the light-emitting layer EL may have a structure in which three blue organic light-emitting layers and one green organic light-emitting layer are stacked.

The common electrode CE may be arranged on the light-emitting layer EL. The common electrode CE may extend continuously in the display area DA across a plurality of pixels. For example, the common electrode CE may entirely or substantially overlap the first, second, and third light-emitting areas LA1, LA2, and LA3 and the light-blocking area BA. The common electrode CE may include a metal, an alloy, a metal nitride, a conductive metal oxide, a transparent conductive material, and/or the like. They may be utilized alone or in combination with each other.

Accordingly, the first light-emitting element LE1 including the first pixel electrode PE1, the light-emitting layer EL, and the common electrode CE may be arranged in the first light-emitting area LA1 on the first substrate SUB1. The second light-emitting element LE2 including the second pixel electrode PE2, the light-emitting layer EL, and the common electrode CE may be arranged in the second light-emitting area LA2 on the first substrate SUB1. The third light-emitting element LE3 including the third pixel electrode PE3, the light-emitting layer EL, and the common electrode CE may be arranged in the third light-emitting area LA3 on the first substrate SUB1. Each of the first, second, and third light-emitting elements LE1, LE2, and LE3 may emit the incident light L1 in a direction toward the second structure 200 (e.g., in the third direction D3).

The encapsulation layer TFE may be arranged on the common electrode CE. The encapsulation layer TFE may protect the first, second, and third light-emitting elements LE1, LE2, and LE3 from external oxygen and moisture. The encapsulation layer TFE may include at least one inorganic layer and at least one organic layer.

The light-blocking pattern BP may be arranged on the encapsulation layer TFE. In some embodiments, the light-blocking pattern BP may overlap the light-blocking area BA. The light-blocking pattern BP may not overlap the first, second, and third light-emitting areas LA1, LA2, and LA3. The light-blocking pattern BP may include a light-blocking material having a relatively high absorbance. For example, the light-blocking pattern BP may include an organic material including a light-blocking material such as a black pigment, a black dye, carbon black, and/or the like. However, the present disclosure is not limited thereto, and the light-blocking pattern BP may include one or more suitable materials having relatively low transmittance and reflectance and relatively high absorbance.

The light-blocking pattern BP may absorb a high angle component of the incident light L1. Because the light-blocking pattern BP absorbs light that is emitted toward another adjacent light-emitting area among the incident light L1 and blocks its transmission, color mixing between adjacent pixels may be prevented or reduced.

For example, in a case of the light-blocking pattern BP adjacent to the second light-emitting area LA2, the light-blocking pattern BP may absorb light that is emitted toward the first light-emitting area LA1 or toward the third light-emitting area LA3 among the incident light L1 emitted by the second light-emitting element LE2 overlapping the second light-emitting area LA2. Accordingly, it may be possible to prevent or reduce the incident light L1 emitted by the second light-emitting element LE2 from being emitted to or toward the first light-emitting area LA1 or the third light-emitting area LA3 to cause color mixing between the first, second, and third light-emitting areas LA1, LA2, and LA3 (e.g., between pixels adjacent to each other).

In some embodiments, a thickness TH of the light-blocking pattern BP may be less than or equal to about 1 μm in the third direction D3. However, the present disclosure is not limited thereto, and the thickness TH of the light-blocking pattern BP may be variously changed according to a purpose, design, and/or the like of the display device 10.

The transmission bank TB may be arranged on the encapsulation layer TFE and the light-blocking pattern BP. The transmission bank TB may overlap the light-blocking area BA. In some embodiments, the transmission bank TB may define a first opening OP1 exposing at least a portion of the light-blocking pattern BP. In one or more embodiments, the transmission bank TB may define a second opening OP2 overlapping each of the first, second, and third light-emitting areas LA1, LA2, and LA3. The second opening OP2 may expose the encapsulation layer TFE.

The transmission bank TB may include a transparent material. For example, the transmission bank TB may include an organic material, such as acrylic resin, epoxy resin, polyimide resin, polyimide resin, and/or the like. These materials may be utilized alone or in combination with each other. Because the transmission bank TB includes a transparent material, the transmission bank TB may transmit light incident on the transmission bank TB.

In some embodiments, a width WD of the light-blocking pattern BP may be greater than or equal to a width W1 of the first opening OP1. In this case, the width WD of the light-blocking pattern BP and the width W1 of the first opening OP1 may be lengths of the light-blocking pattern BP and the first opening OP1 in the first direction D1, respectively. For example, a width of an upper surface of the light-blocking pattern BP may be greater than or equal to a width of the upper surface of the light-blocking pattern BP exposed by the first opening OP1. For example, the width W1 of the first opening OP1 may be the smallest width (e.g., a minimum width) of the light-blocking pattern BP. In this case, light transmitted through the transmission bank TB may be increased (e.g., maximized) (see FIG. 4).

In one or more embodiments, the width WD of the light-blocking pattern BP may be less than or equal to a width W2 of the transmission bank TB. In this case, the width W2 of the transmission bank TB may be a length of the transmission bank TB in the first direction D1. For example, a width of a lower surface of the light-blocking pattern BP may be less than or equal to a width of a lower surface of the transmission bank TB. For example, the width W2 of the transmission bank TB may be the widest width (e.g., a maximum width) of the light-blocking pattern BP. In this case, color mixing between pixels adjacent to each other may be minimized or reduced (see FIG. 5). The width WD of the light-blocking pattern BP may be variously changed between the minimum width and the maximum width.

Each of the first color conversion pattern CCP1 and the second color conversion pattern CCP2 may be arranged in the second opening OP2 defined by the transmission bank TB. The first color conversion pattern CCP1 may be arranged in the second opening OP2 overlapping the second light-emitting area LA2, and the second color conversion pattern CCP2 may be arranged in the second opening OP2 overlapping the third light-emitting area LA3. Each of the first and second color conversion patterns CCP1 and CCP2 may convert the incident light L1 into light in a corresponding wavelength band.

In some embodiments, the first color conversion pattern CCP1 may convert the incident light L1 to emit the second transmitted light L2G. The first color conversion pattern CCP1 may include first quantum dots that are excited by the incident light L1 to emit the second transmitted light L2G. In one or more embodiments, the first color conversion pattern CCP1 may further include first scattering particles, and a first photosensitive polymer in which the first scattering particles are dispersed. For example, as the incident light L1 passes through the first color conversion pattern CCP1, the second transmitted light L2G in a green wavelength band may be emitted from the second light-emitting area LA2, but the present disclosure is not limited thereto.

In some embodiments, the second color conversion pattern CCP2 may convert the incident light L1 to emit the third transmitted light L2R. The second color conversion pattern CCP2 may include second quantum dots that are excited by the incident light L1 to emit the third transmitted light L2R. In one or more embodiments, the second color conversion pattern CCP2 may further include second scattering particles, and a second photosensitive polymer in which the second scattering particles are dispersed. For example, as the incident light L1 passes through the second color conversion pattern CCP2, the third transmitted light L2R in a red wavelength band may be emitted from the third light-emitting area LA3, but the present disclosure is not limited thereto.

The capping layer CPL may be arranged on the first and second color conversion patterns CCP1 and CCP2, the transmission bank TB, and the encapsulation layer TFE. The capping layer CPL may cover the encapsulation layer TFE in the first light-emitting area LA1, may cover the first and second color conversion patterns CCP1 and CCP2 in the second and third light-emitting areas LA2 and LA3, respectively, and may cover the transmission bank TB and the light-blocking pattern BP exposed by the first opening OP1 in the light-blocking area BA. For example, the capping layer CPL may include an inorganic material such as silicon oxide, silicon nitride, silicon oxynitride, and/or the like. These materials may be utilized alone or in combination with each other.

The reflection pattern RP may be arranged on the capping layer CPL. The reflection pattern RP may overlap the light-blocking pattern BP and the transmission bank TB. The reflection pattern RP may overlap the light-blocking area BA. The reflection pattern RP may be arranged along a profile of the capping layer CPL in the light-blocking area BA. In some embodiments, the reflection pattern RP may extend from the upper surface of the light-blocking pattern BP to an upper surface of the transmission bank TB along a side surface of the first opening OP1.

The reflection pattern RP may reflect light incident thereon. Because the reflection pattern RP reflects light transmitted through the transmission bank TB and the capping layer CPL among the incident light L1 or the first, second, and third transmitted light L2B, L2G, and L2R, light efficiency may be improved.

For example, in a case of the reflection pattern RP adjacent to the second light-emitting area LA2, the reflection pattern RP may reflect light transmitted through the transmission bank TB and the capping layer CPL among the incident light L1 emitted by the second light-emitting element LE2 overlapping the second light-emitting area LA2 or the second transmitted light L2G emitted by the first color conversion pattern CCP1 toward the first color conversion pattern CCP1 or the second structure 200. Accordingly, light that deviates from a light path may be recycled and light efficiency may be maximized or increased.

In some embodiments, the reflection pattern RP may include metal. For example, the reflection pattern RP may include aluminum (Al), silver (Ag), gold (Au), and/or the like. However, the present disclosure is not limited thereto, and the reflection pattern RP may include one or more suitable materials having relatively high reflectance.

The transmission pattern LTP may be arranged on the capping layer CPL. The transmission pattern LTP may be arranged in the second opening OP2 defined by the transmission bank TB. The transmission pattern LTP may be arranged in the second opening OP2 overlapping the first light-emitting area LA1.

In one or more embodiments, the transmission pattern LTP may be arranged on the reflection pattern RP. Accordingly, the transmission pattern LTP may overlap the first light-emitting area LA1 and the light-blocking area BA. The transmission pattern LTP overlapping the light-blocking area BA may function as a spacer. In some embodiments, the transmission pattern LTP may be formed through a different process from the first and second color conversion patterns CCP1 and CCP2.

In some embodiments, the transmission pattern LTP may transmit the incident light L1 to emit the first transmitted light L2B. The transmission pattern LTP may include third scattering particles, and a third photosensitive polymer in which the third scattering particles are dispersed. The transmission pattern LTP may not include (e.g., may exclude) quantum dots. For example, as the incident light L1 passes through the transmission pattern LTP, the first transmitted light L2B in a blue wavelength band may be emitted from the first light-emitting area LA1, but the present disclosure is not limited thereto.

The first, second, and third scattering particles may scatter and emit the incident light L1. The first, second, and third scattering particles may include a same material. Each of the first, second, and third photosensitive polymers may include an organic material having light transmittance, such as silicone resin, epoxy resin, and/or the like.

In some embodiments, the second structure 200 may include a second substrate SUB2, a color filter layer CF, a refractive layer LR, and a protective layer PL. The second structure 200 may be arranged on the first structure 100 with the space 400 interposed therebetween.

The second substrate SUB2 may include a transparent material or an opaque material. For example, the second substrate SUB2 may include a rigid glass substrate, a plastic substrate, a flexible film, a metal substrate, and/or the like. These materials may be utilized alone or in combination with each other. Because the display area DA of the display device 10 includes the first, second, and third light-emitting areas LA1, LA2, and LA3 and the light-blocking area BA, the second substrate SUB2 may also define the first, second, and third light-emitting areas LA1, LA2, and LA3 and the light-blocking area BA.

The color filter layer CF may be arranged on the second substrate SUB2 (e.g., below the second substrate SUB2). The color filter layer CF may include a first color filter CF1, a second color filter CF2, and a third color filter CF3.

The first color filter CF1 may overlap the second light-emitting area LA2, the second color filter CF2 may overlap the third light-emitting area LA3, and the third color filter CF3 may overlap the first light-emitting area LA1. Each of the first, second, and third color filters CF1, CF2, and CF3 may selectively transmit light in a corresponding wavelength band.

The first color filter CF1 may transmit the second transmitted light L2G, but may block or reduce light in a wavelength band that is different from that of the second transmitted light L2G. For example, the first color filter CF1 may transmit the second transmitted light L2G in a green wavelength band, but the present disclosure is not limited thereto. Accordingly, in the second light-emitting area LA2, the second transmitted light L2G may pass through the second substrate SUB2 and may be emitted to the outside (e.g., in the third direction D3).

The second color filter CF2 may transmit the third transmitted light L2R, but may block or reduce light in a wavelength band that is different from that of the third transmitted light L2R. For example, the second color filter CF2 may transmit the third transmitted light L2R in a red wavelength band, but the present disclosure is not limited thereto. Accordingly, in the third light-emitting area LA3, the third transmitted light L2R may pass through the second substrate SUB2 and may be emitted to the outside (e.g., in the third direction D3).

The third color filter CF3 may transmit the first transmitted light L2B, but may block or reduce light in a wavelength band that is different from that of the first transmitted light L2B. For example, the third color filter CF3 may transmit the first transmitted light L2B in a blue wavelength band, but the present disclosure is not limited thereto. Accordingly, in the first light-emitting area LA1, the first transmitted light L2B may pass through the second substrate SUB2, and may be emitted to the outside (e.g., in the third direction D3).

In some embodiments, each of the first color filter CF1, the second color filter CF2, and the third color filter CF3 may overlap the light-blocking area BA. For example, the first color filter CF1 may overlap the second light-emitting area LA2 and the light-blocking area BA, but may not overlap the first and third light-emitting areas LA1 and LA3. The second color filter CF2 may overlap the third light-emitting area LA3 and the light-blocking area BA, but may not overlap the first and second light-emitting areas LA1 and LA2. The third color filter CF3 may overlap the first light-emitting area LA1 and the light-blocking area BA, but may not overlap the second and third light-emitting areas LA2 and LA3.

In this case, in the light-blocking area BA, the first, second, and third color filters CF1, CF2, and CF3 may overlap each other in the third direction D3. For example, in the light-blocking area BA, the third color filter CF3 may be arranged on the second color filter CF2 (e.g., below the second color filter CF2), and the first color filter CF1 may be arranged on the third color filter (e.g., below the third color filter CF3). Accordingly, color mixing between the first, second, and third light-emitting areas LA1, LA2, and LA3 adjacent to each other may be prevented or reduced.

The refractive layer LR may be arranged on the color filter layer CF (e.g., below the color filter layer CF). The refractive layer LR may increase light extraction efficiency, and luminance and lifetime of the display device 10 may be increased. For example, the refractive layer LR may include an organic material.

The protective layer PL may be arranged on the refractive layer LR (e.g., below the refractive layer LR). The protective layer PL may cover a lower surface of the refractive layer LR. For example, the protective layer PL may include an inorganic material, such as silicon oxide, silicon nitride, silicon oxynitride, and/or the like. These materials may be utilized alone or in combination with each other.

The display device 10 according to some embodiments of the present disclosure may include the light-blocking pattern BP, the transmission bank TB, and the reflection pattern RP. The light-blocking pattern BP may include a material having a relatively high absorbance. Because the light-blocking pattern BP absorbs light toward adjacent pixels among the incident light L1 emitted by the light-emitting element, color mixing between adjacent pixels may be prevented or reduced.

In one or more embodiments, in a process of forming the transmission bank TB, because an unnecessary portion of the transmission bank TB due to exposure reflection may not be formed by the light-blocking pattern BP, light that is transmitted through the transmission bank TB, and that is not reflected by the reflection pattern RP, may be minimized or reduced. Accordingly, color mixing between pixels adjacent to each other may be further prevented or reduced. In one or more embodiments, because the light transmitted through the transmission bank TB is reflected by the reflection pattern RP, the light efficiency of the display device 10 may be improved.

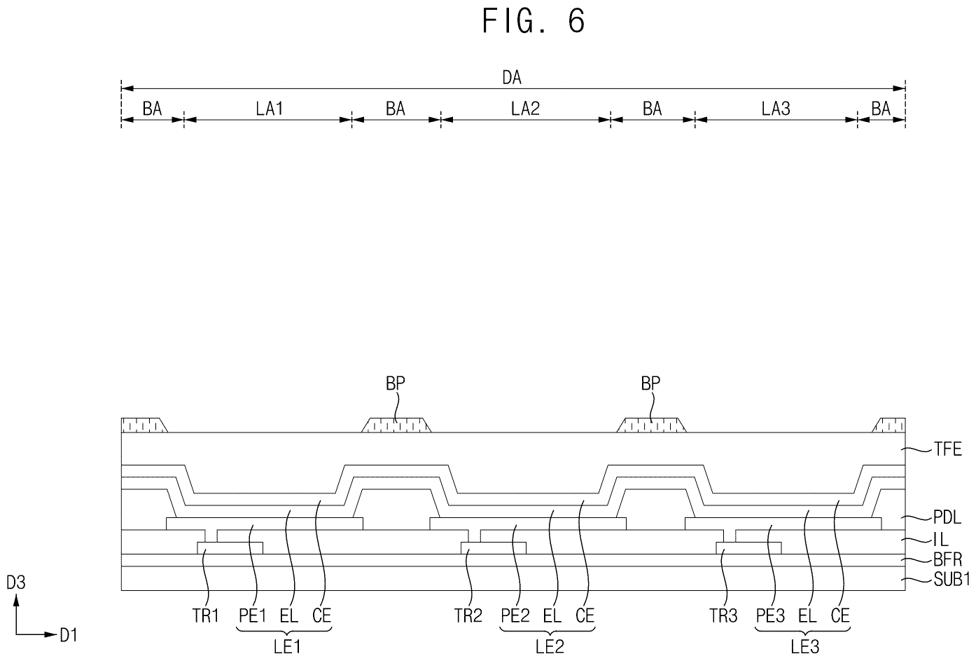

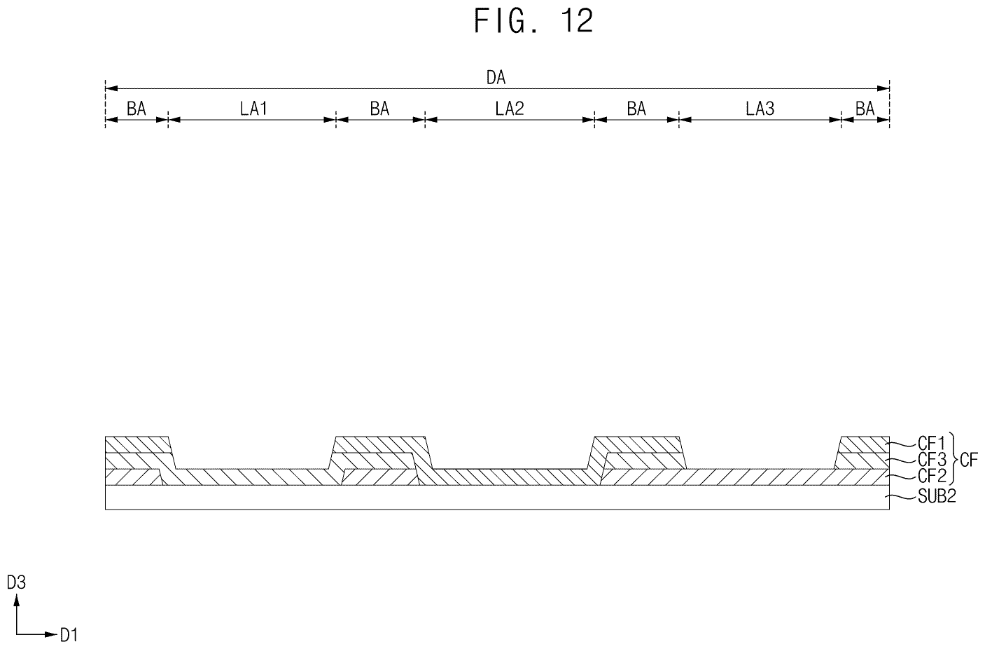

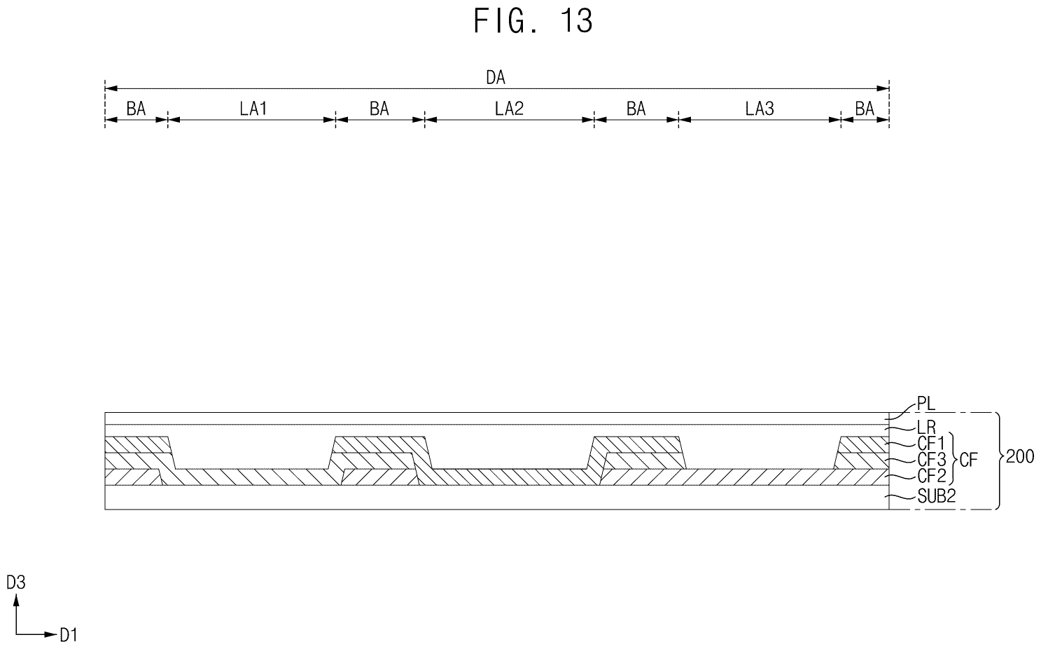

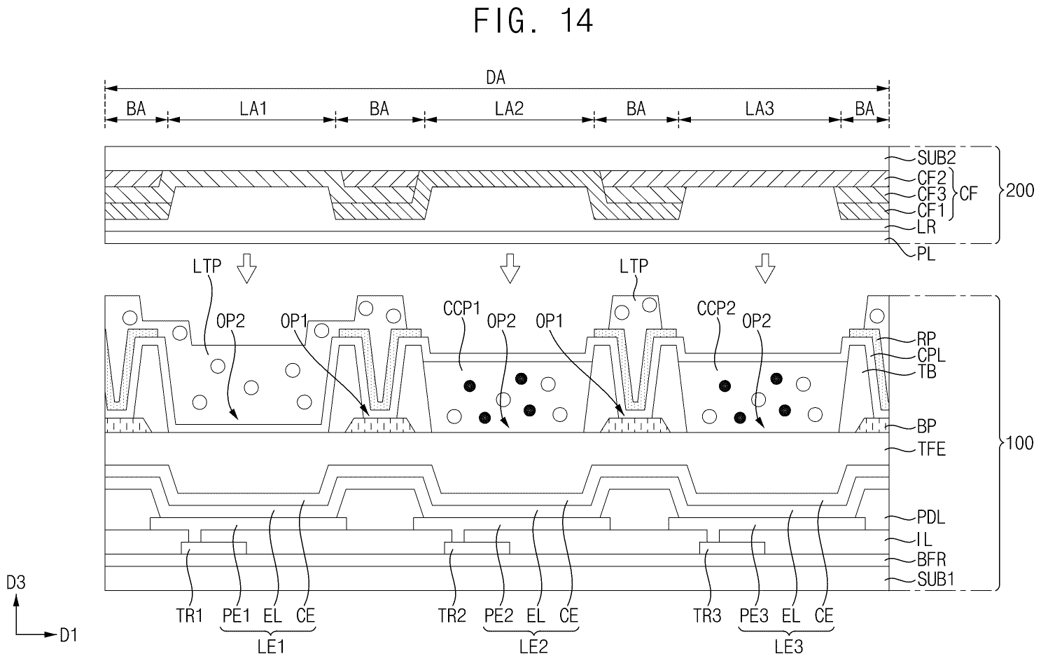

FIGS. 6, 7, 8, 9, 10, 11, 12, 13, and 14 are cross-sectional views illustrating a method of manufacturing the display device of FIG. 3. For example, FIGS. 6, 7, 8, 9, 10, and 11 may be cross-sectional views illustrating a method of manufacturing the first structure 100, and FIGS. 12 and 13 may be cross-sectional views illustrating a method of manufacturing the second structure 200.

The method of manufacturing the display device described with reference to FIGS. 6, 7, 8, 9, 10, 11, 12, 13, and 14 may be a method of manufacturing the display device 10 described with reference to FIGS. 1, 2, 3, 4, and 5. Therefore, redundant descriptions will not be provided or may be simplified.

Referring to FIG. 6, the buffer layer BFR, the first, second, and third transistors TR1, TR2, and TR3, the insulating layer IL, the first, second, and third pixel electrodes PE1, PE2, and PE3, the pixel-defining layer PDL, the light-emitting layer EL, the common electrode CE, and the encapsulation layer TFE may be sequentially formed on the first substrate SUB1.

A light-blocking layer may be formed on the encapsulation layer TFE. The light-blocking layer may include a light-blocking material having a relatively high absorbance. For example, the light-blocking layer may include an organic material including a light-blocking material, such as a black pigment, a black dye, carbon black, and/or the like.

In some embodiments, the light-blocking layer may be patterned through a photolithography process to form the light-blocking pattern BP. The light-blocking pattern BP may overlap the light-blocking area BA, and may not overlap the first, second, and third light-emitting areas LA1, LA2, and LA3.

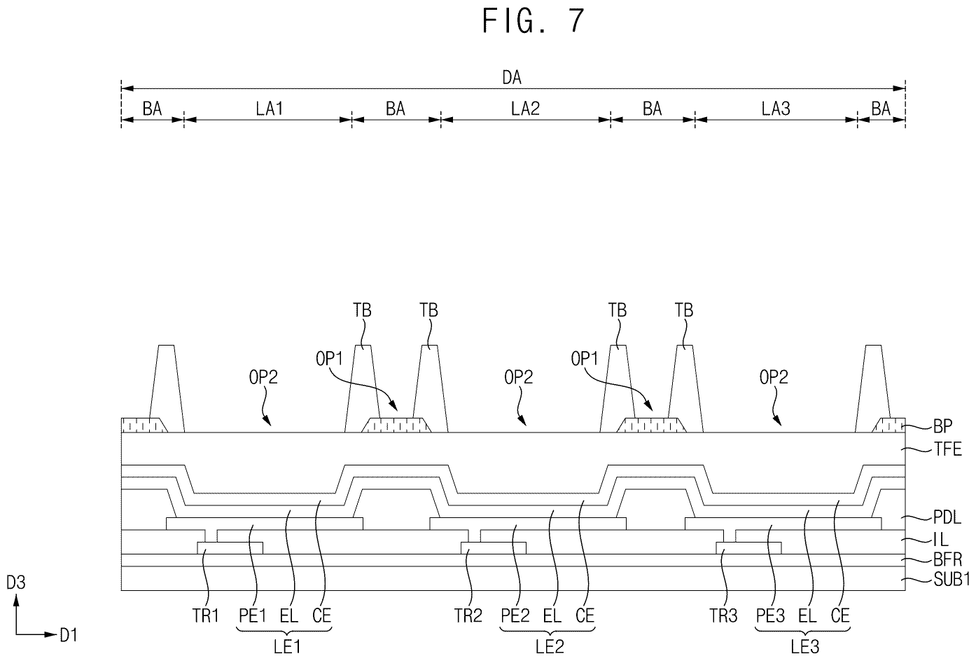

Referring to FIG. 7, a bank layer may be formed on the encapsulation layer TFE and the light-blocking pattern BP. For example, the bank layer may include a transparent organic material. In some embodiments, the bank layer may be patterned through a photolithography process to form the transmission bank TB. The transmission bank TB may overlap the light-blocking area BA.

In the photolithography process, light reflected by lower components during exposure may be absorbed by the light-blocking pattern BP. Accordingly, the transmission bank TB may be formed so as not to include an unnecessary portion due to exposure reflection.

The transmission bank TB may be formed to define the first opening OP1 exposing at least a portion of the light-blocking pattern BP. In one or more embodiments, the transmission bank TB may be formed to define the second opening OP2 overlapping each of the first, second, and third light-emitting areas LA1, LA2, and LA3.

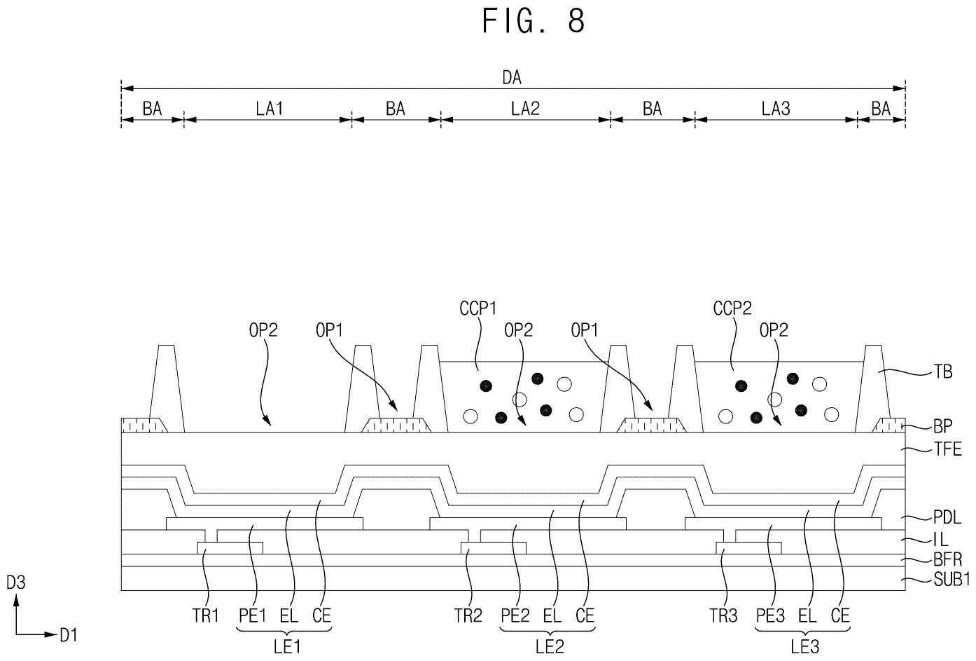

Referring to FIG. 8, the first color conversion pattern CCP1 may be formed in the second opening OP2 overlapping the second light-emitting area LA2, and the second color conversion pattern CCP2 may be formed in the second opening OP2 overlapping the third light-emitting area LA3. The first and second color conversion patterns CCP1 and CCP2 may be formed through an inkjet process.

For example, the first color conversion pattern CCP1 may be formed by repeatedly dropping a first ink composition into the second opening OP2 overlapping the second light-emitting area LA2. The first ink composition may be a material forming the first color conversion pattern CCP1.

In one or more embodiments, the second color conversion pattern CCP2 may be formed by repeatedly dropping a second ink composition into the second opening OP2 overlapping the third light-emitting area LA3. The second ink composition may be a material forming the second color conversion pattern CCP2.

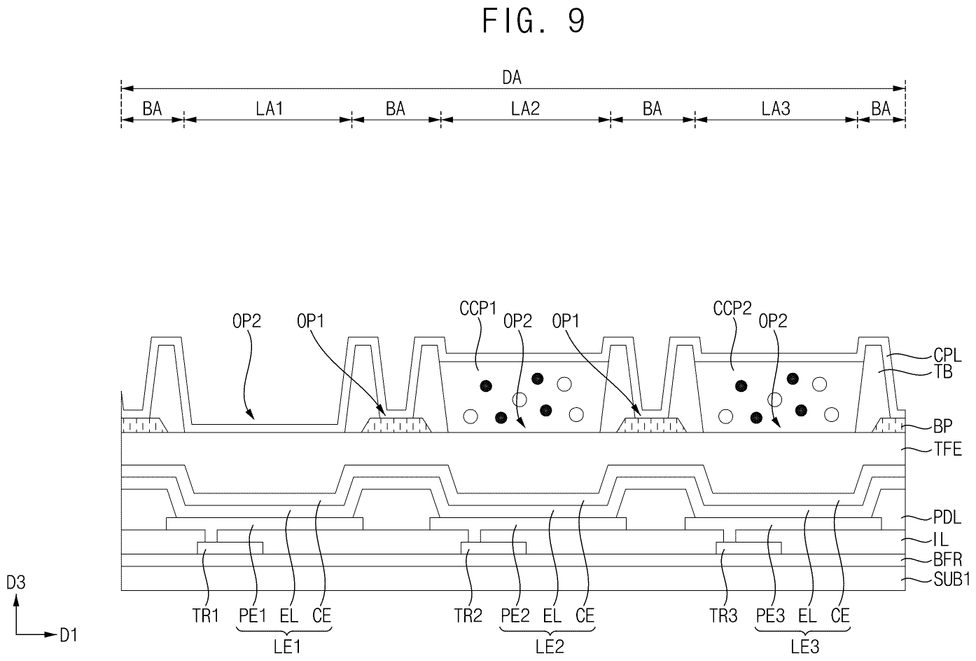

Referring to FIG. 9, the capping layer CPL may be formed on the encapsulation layer TFE, the transmission bank TB, and the first and second color conversion patterns CCP1 and CCP2. The capping layer CPL may be formed to cover the encapsulation layer TFE exposed by the second opening OP2 in the first light-emitting area LA1, cover the first and second color conversion patterns CCP1 and CCP2 in the second and third light-emitting areas LA2 and LA3, respectively, and cover the transmission bank TB and the light-blocking pattern BP exposed by the first opening OP1 in the light-blocking area BA.

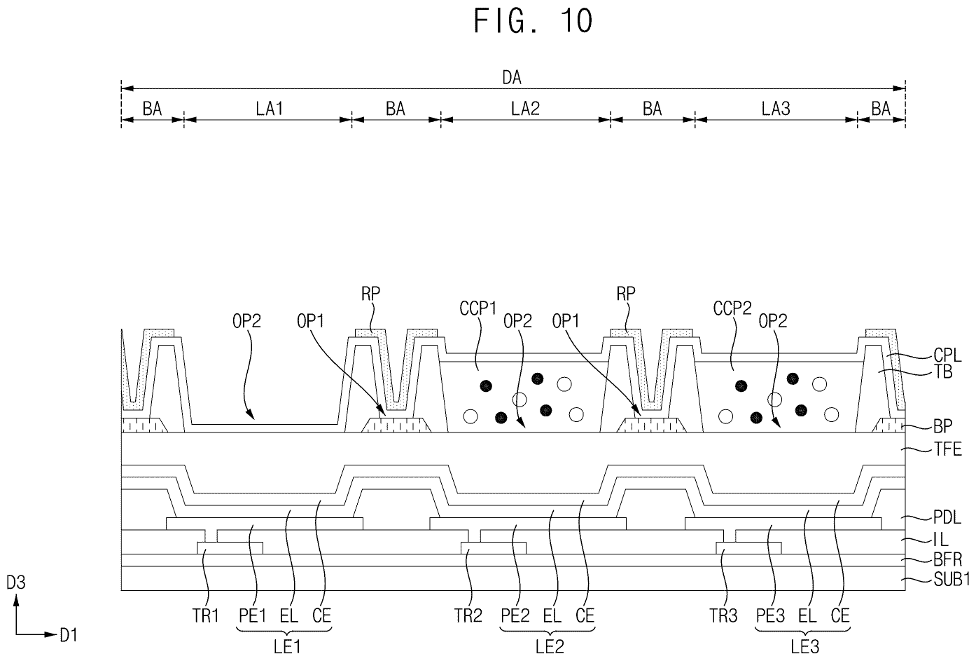

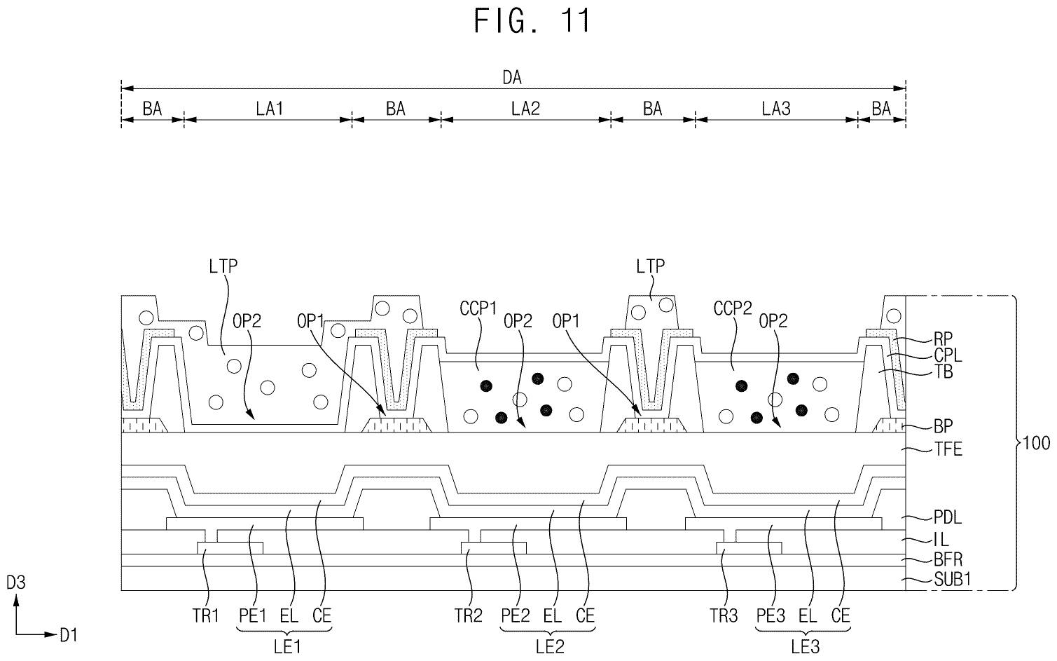

Referring to FIG. 10, a reflection layer may be formed on the capping layer CPL. The reflection layer may include a material having a relatively high reflectance. For example, the reflection layer may include a metal.

In some embodiments, the reflection layer may be patterned through a photolithography process to form the reflection pattern RP. The reflection pattern RP may overlap the light-blocking pattern BP and the transmission bank TB. In some embodiments, the reflection pattern RP may be formed to extend from the upper surface of the light-blocking pattern BP to the upper surface of the transmission bank TB along the side surface of the first opening OP1.

Referring to FIG. 11, a transmission layer may be formed on the capping layer CPL and the reflection pattern RP. The transmission layer may include the third scattering particles and the third photosensitive polymer. The transmission layer may not include (e.g., may exclude) quantum dots.

In some embodiments, the transmission layer may be patterned through a photolithography process to form the transmission pattern LTP. The transmission pattern LTP may be formed in the second opening OP2 overlapping the first light-emitting area LA1 and on the reflection pattern RP. Thus, in some embodiments, the transmission pattern LTP may not be formed through an inkjet process.

Accordingly, the first structure 100 illustrated in FIG. 3 may be formed.

Referring to FIG. 12, the second color filter CF2 may be formed on the second substrate SUB2. The second color filter CF2 may overlap the third light-emitting area LA3 and the light-blocking area BA.

The third color filter CF3 may be formed on the second substrate SUB2 and the second color filter CF2. The third color filter CF3 may overlap the first light-emitting area LA1 and the light-blocking area BA.

The first color filter CF1 may be formed on the second substrate SUB2 and the third color filter CF3. The first color filter CF1 may overlap the second light-emitting area LA2 and the light-blocking area BA.

Referring to FIG. 13, the refractive layer LR and the protective layer PL may be sequentially formed on the color filter layer CF. Accordingly, the second structure 200 illustrated in FIG. 3 may be formed.

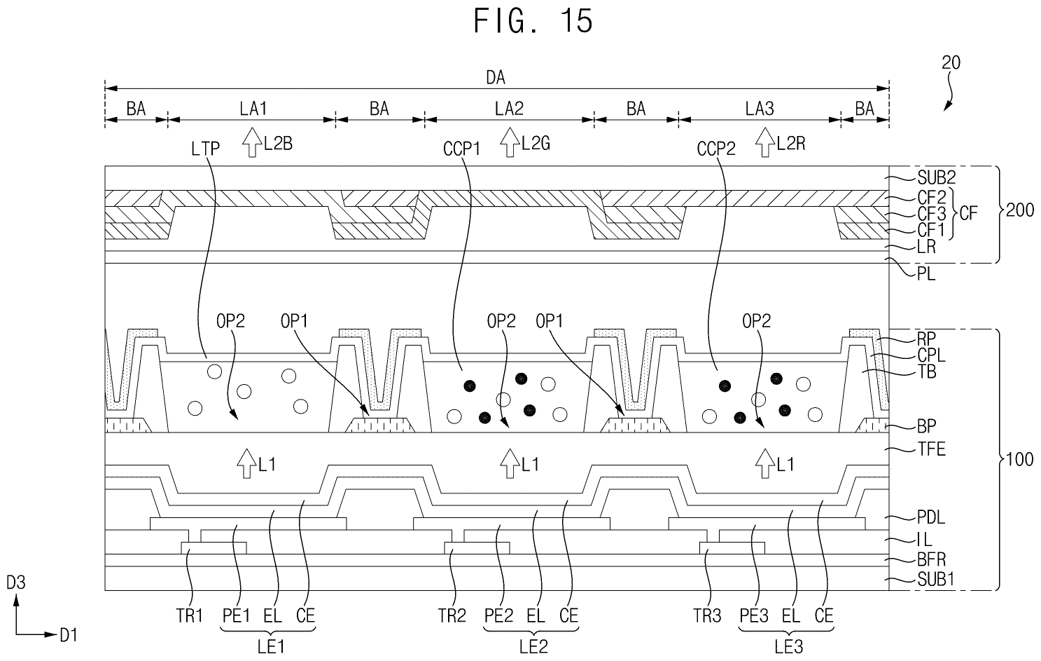

Referring to FIGS. 3 and 14, the first structure 100 and the second structure 200 may be coupled to each other. For example, the first structure 100 and the second structure 200 may be coupled to each other by a sealing member (e.g., the sealing member 300 of FIG. 2). Accordingly, the display device 10 illustrated in FIG. 3 may be manufactured.

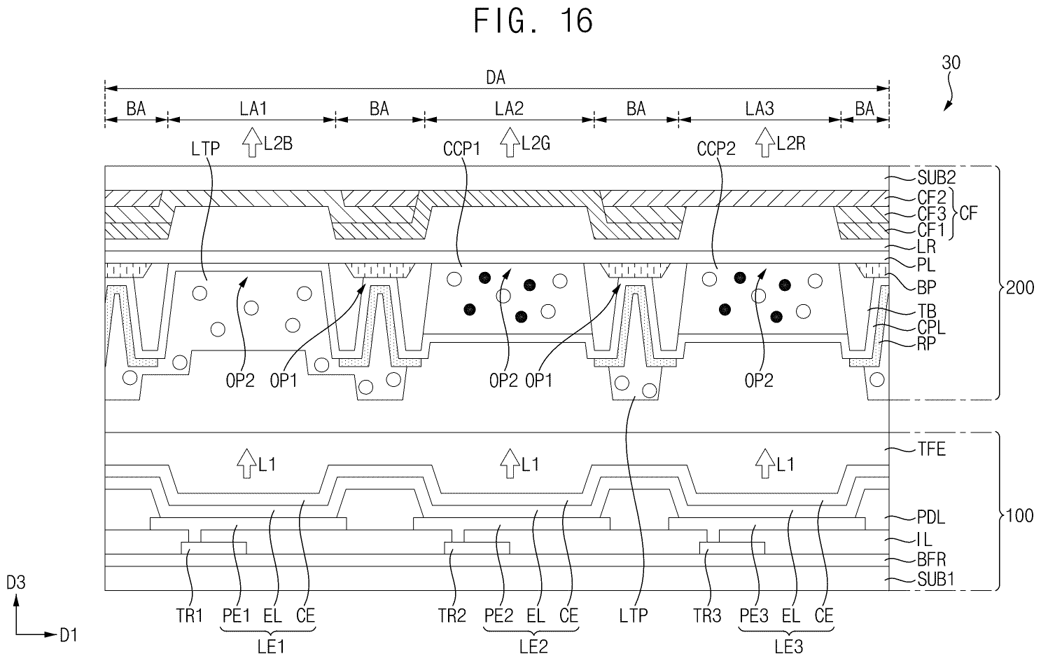

FIG. 15 is a cross-sectional view illustrating a display device according to one or more other embodiments of the present disclosure. For example, FIG. 15 may correspond to the cross-sectional view of FIG. 3. For example, FIG. 15 may be a cross-sectional view illustrating an example of a display area DA included in a display device 20.

A display device 20 described with reference to FIG. 15 may be substantially the same as or similar to the display device 10 described with reference to FIGS. 1, 2, 3, 4, and 5, except for a transmission pattern LTP and a capping layer CPL. Therefore, redundant descriptions will not be provided or may be simplified.

Referring to FIG. 15, the display device 20 may include a display area DA, and the display area DA may include a first light-emitting area LA1, a second light-emitting area LA2, a third light-emitting area LA3, and a light-blocking area BA. The light-blocking area BA may be arranged between the first, second, and third light-emitting areas LA1, LA2, and LA3 adjacent to each other.

The display device 20 may include a first structure 100 and a second structure 200 facing each other. The second structure 200 may be spaced apart from the first structure 100 in a third direction D3. Incident light L1 generated from the first structure 100 may be emitted to outside through the first, second, and third light-emitting areas LA1, LA2, and LA3 (e.g., in the third direction D3).

The first, second, and third light-emitting areas LA1, LA2, and LA3 may emit light in different wavelength bands. For example, the first light-emitting area LA1 may emit first transmitted light L2B in a blue wavelength band, the second light-emitting area LA2 may emit second transmitted light L2G in a green wavelength band, and the third light-emitting area LA3 may emit third transmitted light L2R in a red wavelength band, but the present disclosure is not limited thereto.

In some embodiments, the first structure 100 may include a first substrate SUB1, a buffer layer BFR, first, second, and third transistors TR1, TR2, and TR3, an insulating layer IL, a pixel-defining layer PDL, first, second, and third light-emitting elements LE1, LE2, and LE3, an encapsulation layer TFE, a light-blocking pattern BP, a transmission bank TB, a transmission pattern LTP, a first color conversion pattern CCP1, a second color conversion pattern CCP2, a capping layer CPL, and a reflection pattern RP.

Here, the first light-emitting element LE1 may include a first pixel electrode PE1, a light-emitting layer EL, and a common electrode CE, the second light-emitting element LE2 may include a second pixel electrode PE2, the light-emitting layer EL, and the common electrode CE, and the third light-emitting element LE3 may include a third pixel electrode PE3, the light-emitting layer EL, and the common electrode CE.

The buffer layer BFR, the first, second, and third transistors TR1, TR2, and TR3, the insulating layer IL, the first, second, and third pixel electrodes PE1, PE2, and PE3, the pixel-defining layer PDL, the light-emitting layer EL, the common electrode CE, and the encapsulation layer TFE may be sequentially arranged on the first substrate SUB1.

The light-blocking pattern BP may be arranged in the light-blocking area BA on the encapsulation layer TFE. The light-blocking pattern BP may include a light-blocking material having a relatively high absorbance. For example, the light-blocking pattern BP may include an organic material including a light-blocking material such as a black pigment, a black dye, carbon black, and/or the like.

The light-blocking pattern BP may absorb a high angle component of the incident light L1. Because the light-blocking pattern BP absorbs light that is emitted toward another adjacent light-emitting area among the incident light L1 to block or reduce transmission, color mixing between the first, second, and third light-emitting areas LA1, LA2, and LA3 adjacent to each other (e.g., between pixels adjacent to each other) may be prevented or reduced. In some embodiments, a thickness of the light-blocking pattern BP may be less than or equal to about 1 μm.

The transmission bank TB may be arranged in the light-blocking area BA on the encapsulation layer TFE and the light-blocking pattern BP. In some embodiments, the transmission bank TB may define a first opening OP1 exposing at least a portion of the light-blocking pattern BP, and may define a second opening OP2 overlapping the first, second, and third light-emitting areas LA1, LA2, and LA3 and exposing the encapsulation layer TFE. In some embodiments, the transmission bank TB may include a transparent material, and may transmit light incident on the transmission bank TB.

In some embodiments, a width of the first opening OP1 may be the smallest width (e.g., a minimum width) of the light-blocking pattern BP, and a width of the transmission bank TB may be the largest width (e.g., a maximum width) of the light-blocking pattern BP.

Each of the transmission pattern LTP, the first color conversion pattern CCP1, and the second color conversion pattern CCP2 may be arranged in the second opening OP2 defined by the transmission bank TB. The transmission pattern LTP may be arranged in the second opening OP2 overlapping the first light-emitting area LA1, the first color conversion pattern CCP1 may be arranged in the second opening OP2 overlapping the second light-emitting area LA2, and the second color conversion pattern CCP2 may be arranged in the second opening OP2 overlapping the third light-emitting area LA3.

The transmission pattern LTP may transmit the incident light L1, and each of the first and second color conversion patterns CCP1 and CCP2 may convert the incident light L1 into light in a corresponding wavelength band.

In some embodiments, the transmission pattern LTP may transmit the incident light L1 to emit the first transmitted light L2B. The first color conversion pattern CCP1 may convert the incident light L1 to emit the second transmitted light L2G. The second color conversion pattern CCP2 may convert the incident light L1 to emit the third transmitted light L2R.

In some embodiments, each of the transmission pattern LTP and the first and second color conversion patterns CCP1 and CCP2 may be formed through an inkjet process. Thus, the transmission pattern LTP may not be formed through a photolithography process.

The capping layer CPL may be arranged on the transmission pattern LTP, the first and second color conversion patterns CCP1 and CCP2, and the transmission bank TB. The capping layer CPL may cover the transmission pattern LTP and the first and second color conversion patterns CCP1 and CCP2 in the first, second, and third light-emitting areas LA1, LA2, and LA3, respectively, and may cover the transmission bank TB and the light-blocking pattern BP exposed by the first opening OP1 in the light-blocking area BA.

The reflection pattern RP may be arranged in the light-blocking area BA on the capping layer CPL. In some embodiments, the reflection pattern RP may extend from an upper surface of the light-blocking pattern BP to an upper surface of the transmission bank TB along a side surface of the first opening OP1.

In some embodiments, the reflection pattern RP may include a metal. The reflection pattern RP may reflect light incident on the reflection pattern RP. Because the reflection pattern RP reflects light that is transmitted through the transmission bank TB and through the capping layer CPL among the incident light L1 or the first, second, and third transmitted light L2B, L2G, and L2R, light efficiency may be improved.

In some embodiments, the second structure 200 may include a second substrate SUB2, a color filter layer CF, a refractive layer LR, and a protective layer PL. The color filter layer CF may include a first color filter CF1, a second color filter CF2, and a third color filter CF3. The color filter layer CF, the refractive layer LR, and the protective layer PL may be sequentially arranged on the second substrate SUB2 (e.g., below the second substrate SUB2).

FIG. 16 is a cross-sectional view illustrating a display device according to still one or more other embodiments of the present disclosure. For example, FIG. 16 may correspond to the cross-sectional view of FIG. 3. Thus, FIG. 16 may be a cross-sectional view illustrating an example of a display area DA included in a display device 30.

A display device 30 described with reference to FIG. 16 may be substantially the same as or similar to the display device 10 described with reference to FIGS. 1, 2, 3, 4, and 5, except that a light-blocking pattern BP, a transmission bank TB, a first color conversion pattern CCP1, a second color conversion pattern CCP2, a capping layer CPL, and a transmission pattern LTP are included in a second structure 200, for example, instead of in the first structure 100. Therefore, redundant descriptions will not be provided or may be simplified.

Referring to FIG. 16, the display device 30 may include a display area DA, and the display area DA may include a first light-emitting area LA1, a second light-emitting area LA2, a third light-emitting area LA3, and a light-blocking area BA. The light-blocking area BA may be arranged between the first, second, and third light-emitting areas LA1, LA2, and LA3 adjacent to each other.

The display device 30 may include a first structure 100 and a second structure 200 facing each other. The second structure 200 may be spaced apart from the first structure 100 in a third direction D3. Incident light L1 generated from the first structure 100 may be emitted to outside through the first, second, and third light-emitting areas LA1, LA2, and LA3 (e.g., in the third direction D3).

The first, second, and third light-emitting areas LA1, LA2, and LA3 may emit light in different wavelength bands. For example, the first light-emitting area LA1 may emit first transmitted light L2B in a blue wavelength band, the second light-emitting area LA2 may emit second transmitted light L2G in a green wavelength band, and the third light-emitting area LA3 may emit third transmitted light L2R in a red wavelength band, but the present disclosure is not limited thereto.

In some embodiments, the first structure 100 may include a first substrate SUB1, a buffer layer BFR, first, second, and third transistors TR1, TR2, and TR3, an insulating layer IL, a pixel-defining layer PDL, first, second, and third light-emitting elements LE1, LE2, and LE3, and an encapsulation layer TFE.

Here, the first light-emitting element LE1 may include a first pixel electrode PE1, a light-emitting layer EL, and a common electrode CE, the second light-emitting element LE2 may include a second pixel electrode PE2, the light-emitting layer EL, and the common electrode CE, and the third light-emitting element LE3 may include a third pixel electrode PE3, the light-emitting layer EL, and the common electrode CE.

The buffer layer BFR, the first, second, and third transistors TR1, TR2, and TR3, the insulating layer IL, the first, second, and third pixel electrodes PE1, PE2, and PE3, the pixel-defining layer PDL, the light-emitting layer EL, the common electrode CE, and the encapsulation layer TFE may be sequentially arranged on the first substrate SUB1.

In some embodiments, the second structure 200 may include a second substrate SUB2, a color filter layer CF, a refractive layer LR, a protective layer PL, a light-blocking pattern BP, a transmission bank TB, a first color conversion pattern CCP1, a second color conversion pattern CCP2, a capping layer CPL, a reflection pattern RP, and a transmission pattern LTP.

The color filter layer CF may include a first color filter CF1, a second color filter CF2, and a third color filter CF3. The color filter layer CF, the refractive layer LR, and the protective layer PL may be sequentially arranged on the second substrate SUB2 (e.g., below the second substrate SUB2).

The light-blocking pattern BP may be arranged in the light-blocking area BA on the protective layer PL (e.g., below the protective layer PL). The light-blocking pattern BP may include a light-blocking material having a relatively high absorbance. For example, the light-blocking pattern BP may include an organic material including a light-blocking material, such as a black pigment, a black dye, carbon black, and/or the like. In some embodiments, a thickness of the light-blocking pattern BP may be less than or equal to about 1 μm.

The transmission bank TB may be arranged in the light-blocking area BA on the protective layer PL (e.g., below the protective layer PL) and the light-blocking pattern BP. In some embodiments, the transmission bank TB may define a first opening OP1 exposing at least a portion of the light-blocking pattern BP and a second opening OP2 overlapping the first, second, and third light-emitting areas LA1, LA2, and LA3 and exposing the protective layer PL. The transmission bank TB may transmit light incident on the transmission bank TB. In some embodiments, a width of the first opening OP1 may be the smallest width (e.g., a minimum width) of the light-blocking pattern BP, and a width of the transmission bank TB may be the largest width (e.g., a maximum width) of the light-blocking pattern BP.

The first color conversion pattern CCP1 may be arranged in the second opening OP2 overlapping the second light-emitting area LA2, and the second color conversion pattern CCP2 may be arranged in the second opening OP2 overlapping the third light-emitting area LA3. In some embodiments, the first color conversion pattern CCP1 may convert the incident light L1 to emit the second transmitted light L2G, and the second color conversion pattern CCP2 may convert the incident light L1 to emit the third transmitted light L2R.

The capping layer CPL may be arranged on second color conversion patterns CCP1 and CCP2 (e.g., below the first and second color conversion patterns CCP1 and CCP2), the transmission bank TB, and the encapsulation layer TFE. The capping layer CPL may cover the encapsulation layer TFE in the first light-emitting area LA1, may cover the first and second color conversion patterns CCP1 and CCP2 in the second and third light-emitting areas LA2 and LA3, respectively, and may cover the transmission bank TB and the light-blocking pattern BP exposed by the first opening OP1 in the light-blocking area BA.

The reflection pattern RP may be arranged in the light-blocking area BA on the capping layer CPL (e.g., below the capping layer CPL). In some embodiments, the reflection pattern RP may extend from a lower surface of the light-blocking pattern BP to a lower surface of the transmission bank TB along a side surface of the first opening OP1. The reflection pattern RP may reflect light incident on the reflection pattern RP.

The transmission pattern LTP may be arranged in the second opening OP2 overlapping the first light-emitting area LA1. In some embodiments, the transmission pattern LTP may transmit the incident light L1 to emit the first transmitted light L2B.

In some embodiments, the transmission pattern LTP may be formed through a photolithography process, and may be further arranged in the light-blocking area BA on the reflection pattern RP (e.g., below the reflection pattern RP). However, the present disclosure is not limited thereto. In some embodiments, the transmission pattern LTP may be formed through an inkjet process, and may not be further arranged on the reflection pattern RP (e.g., below the reflection pattern RP). In one or more embodiments, the capping layer CPL may cover the transmission pattern LTP in the first light-emitting area LA1.

The embodiments of the present disclosure can be applied to one or more suitable display devices. For example, the embodiments of the present disclosure are applicable to one or more suitable display devices such as display devices for vehicles, ships and aircraft, portable communication devices, display devices for exhibition or information transmission, medical display devices, and/or the like.

The foregoing is illustrative of embodiments and is not to be construed as limiting thereof. Although a few embodiments have been described, those skilled in the art will readily appreciate that many modifications are possible in the embodiments without materially departing from the aspects of the present disclosure. Accordingly, all such modifications are intended to be included within the scope of the present disclosure as defined in the claims. Therefore, it is to be understood that the foregoing is illustrative of one or more suitable embodiments and is not to be construed as limited to the specific embodiments disclosed, and that modifications to the disclosed embodiments, as well as other embodiments, are intended to be included within the scope of the appended claims and their functional equivalents.

What is claimed is:

1. A display device comprising:
a substrate defining a light-emitting area, and a light-blocking area adjacent to the light-emitting area;
a light-blocking pattern at the light-blocking area above the substrate;
a transmission bank above the light-blocking pattern, and defining a first opening exposing at least a portion of the light-blocking pattern; and
a reflection pattern above the light-blocking pattern exposed by the first opening and the transmission bank.

2. The display device of claim 1, wherein the reflection pattern extends from an upper surface of the light-blocking pattern to an upper surface of the transmission bank along a side surface of the first opening.

3. The display device of claim 1, wherein a thickness of the light-blocking pattern is less than or equal to about 1 μm.

4. The display device of claim 1, wherein a width of the light-blocking pattern is greater than or equal to a width of the first opening.

5. The display device of claim 4, wherein the width of the light-blocking pattern is less than or equal to a width of the transmission bank.

6. The display device of claim 1, further comprising a color conversion pattern at the light-emitting area above the substrate.

7. The display device of claim 6, wherein the transmission bank further defines a second opening overlapping the light-emitting area, and
wherein the color conversion pattern is in the second opening.

8. The display device of claim 7, further comprising a transmission pattern at the light-emitting area above the substrate.

9. The display device of claim 8, wherein the transmission bank further defines a third opening overlapping the light-emitting area, and
wherein the transmission pattern is in the third opening and above the reflection pattern.

10. The display device of claim 1, wherein the reflection pattern comprises metal.

11. The display device of claim 1, further comprising a light-emitting layer between the substrate and the light-blocking pattern.

12. A method of manufacturing a display device, the method comprising:
forming a light-blocking pattern at a light-blocking area above a substrate defining the light-blocking area, and a light-emitting area adjacent to the light-blocking area;
forming a transmission bank above the light-blocking pattern defining a first opening exposing at least a portion of the light-blocking pattern; and
forming a reflection pattern above the light-blocking pattern exposed by the first opening and above the transmission bank.

13. The method of claim 12, wherein the reflection pattern extends from an upper surface of the light-blocking pattern to an upper surface of the transmission bank along a side surface of the first opening.

14. The method of claim 12, wherein a thickness of the light-blocking pattern is less than or equal to about 1 μm.

15. The method of claim 12, wherein a width of the light-blocking pattern is greater than or equal to a width of the first opening.

16. The method of claim 15, wherein the width of the light-blocking pattern is less than or equal to a width of the transmission bank.

17. The method of claim 12, further comprising forming a color conversion pattern at the light-emitting area above the substrate after forming the transmission bank and before forming the reflection pattern.

18. The method of claim 17, wherein the transmission bank further defines a second opening overlapping the light-emitting area, and
wherein the color conversion pattern is formed in the second opening.

19. The method of claim 18, further comprising forming a transmission pattern at the light-emitting area above the substrate after forming the reflection pattern.

20. The method of claim 19, wherein the transmission bank further defines a third opening overlapping the light-emitting area, and
wherein the transmission pattern is formed in the third opening and above the reflection pattern.

21. The method of claim 12, further comprising forming a light-emitting layer on the substrate before forming the light-blocking pattern.
